(19) United States
(12) Patent Application Publication
(10) Pub. No.: US 2013/0249358 A1
(43) Pub. Date: Sep. 26, 2013

(54) Portable Mobile Device Protective Cover

(71) Applicant: HUCKLEBERRY TOYS, Northridge, CA (US)

(72) Inventor: Hugo Stevenson, Northridge, CA (US)

(73) Assignee: HUCKLEBERRY TOYS, Northridge, CA (US)

(21) Appl. No.: 13/840,652

(22) Filed: Mar. 15, 2013

Related U.S. Application Data
(60) Provisional application No. 61/614,988, filed on Mar. 23, 2012.

(51) Int. Cl. H05K 5/00; B29C 45/00

(52) U.S. Cl. CPC H05K 5/0004; B29C 45/0053
USPC 312/223.1; 29/428; 264/328.1

(57) ABSTRACT

The present invention relates to a three-dimensional protective cover for portable mobile devices. These covers are intended to protect the device in a decorative and personalized manner. The covers are also intended to provide the ability to view the device in an upright orientation.

This application claims priority to U.S. Provisional Patent Application No. 61/614,988, filed on Mar. 23, 2012, which application is incorporated herein by reference in its entirety.

### FIELD OF THE INVENTION

The present invention relates to protective covers for portable mobile devices. These protective covers are intended to protect the device at the same time as being decorative. These protective covers are also intended to provide the ability to view the device in an upright orientation.

### BACKGROUND OF THE INVENTION

The advent of portable mobile devices that connect a user to a network has resulted in a highly mobile workplace and life for many people. Portable mobile devices provide users with access to networks such as the public switched telephone network and the Internet (e.g., using the wireless application protocol (WAP)), as well as local applications. These handheld communication devices facilitate both voice and electronic mail communications and are virtually indispensable to a wide range of users. In just about every profession, users may capitalize on the many advantages portable communication devices provide, including quick access to phone service, e-mails, and the web, and the ubiquitous personal data assistants (PDAs) have addressed this need.

These mobile devices, however, are delicate. If dropped or otherwise disturbed, these mobile devices can break or shatter. Breakage can be cosmetic or render the device completely useless. To reduce the possibility of such damage, a variety of protective covers for portable mobile devices are widely available. These protective covers are generally a covering made of rubber, plastic, or other materials that surround the device in various fashions. They are available in a wide range of colors and patterns. Yet, these protective covers fail to allow for a three-dimensional character or logo to be displayed and still retain the device's functionality. Thus, there is a need for a protective cover for portable mobile devices, which is both functional and decorative using a three-dimensional design.

These available mobile devices are also oftentimes difficult to be used without being held. Thus, if a user needs both hands to do something else, the user needs to place the device flat on its posterior side onto a surface. If the user wants to view something on the device, the user must lean over top of the device to view it because the user is unable to view the device in a hands-free upright position. Thus, there is a need for a cover for a portable mobile device which provides the device to be viewed in an hands-free upright position, which is both functional and decorative using a three-dimensional design.

### BRIEF DESCRIPTION OF THE INVENTION

The invention relates to a portable mobile device protective cover application that has a three-dimensional depiction of a character, logo, animal, or any other three-dimensional object. The protective cover can be prepared using, for example, an injection molding protocol, among other methods known in the art. The protective cover may be made up of one or more pieces.

In one embodiment, the invention relates to a protective cover for a portable mobile device, comprising a three-dimensional top portion and a three-dimensional bottom portion, wherein the top and bottom portions are operably separable from each other. The portable mobile device can be placed into the protective cover, by placing the three-dimensional top portion over the top of the device, and then placing the three-dimensional bottom portion under the bottom of the device. The three-dimensional top and bottom portions can be slid together to be in communication with each other to form a single unit. The three-dimensional top and bottom portions may form a single unit by a sliding fastener, or any other mechanical connector or fastener. The protective cover can be prepared for any type of device that may be placed into the cover and thus protected against breakage when dropped or otherwise impacted.

In another embodiment, the protective cover can be two pieces in which the top portion can depict a head, while the bottom portion can depict a torso. Together, the top and bottom portions depict a three-dimensional design, which can be a character, an animal, or a three dimensional logo.

In another embodiment, the protective cover can be one single piece. The portable mobile device can be mechanically fastened or connected to the three-dimensional protective cover.

In another embodiment, the single piece three-dimensional protective cover, or the two-piece three-dimensional protective cover, can have a lower portion with a thickness and weight great enough to hold the portable mobile device in an upright position when the lower portion of the portable mobile device is placed in an upright position on a surface.

In another embodiment, the invention relates to a method of manufacturing the protective cover for a portable mobile device comprising preparing two-dimensional drawings of a desired design; loading the two-dimensional drawings into a computer; preparing a three-dimensional rendering of the design; preparing a tool of the design; injecting a material into the tool; removing and separating portions of protective cover from the tool; and forming the protective cover from the separated portions.

The method of manufacturing the protective cover for a portable mobile device can also include the steps of cleaning the protective cover; painting the protective cover; welding the desired portions together to form the protective cover; and spraying a rubberized coating onto the painted protective cover.

In still another embodiment, the invention relates to a method of using a two-piece portable mobile device protective cover comprising separating a top portion of the protective cover having a three-dimensional design from a bottom portion of the protective cover having a three-dimensional design; placing the portable mobile device into the bottom portion of the protective cover; placing the top portion of the protective cover onto the top of the portable mobile device so that the top portion and the bottom portion hold the portable mobile device in place. The top and bottom portion of the protective device can form a single unit by a mechanical connector or fastener, and the portable mobile device can be held in place and protected from damage incurred by dropping or other impact.

Other systems, methods, features, and advantages of the present invention will be or will become apparent to one with skill in the art upon examination of the following figures and detailed description. All such additional systems, methods, features, and advantages are included within this description, are within the scope of the invention, and are protected by the accompanying claims.

### BRIEF DESCRIPTION OF THE FIGURES

The invention may be better understood by reference to the detailed description when considered in connection with the accompanying drawings. The components in the figures are not necessarily to scale, emphasis instead being placed upon illustrating the principles of the invention.

FIG. 1 illustrates a front view of one embodiment of the invention of a portable mobile device protective cover depicting a dog in a three-dimensional design.

FIG. 2A illustrates a front view of one embodiment of a three-dimensional rendering for a one-piece portable mobile device protective cover depicting a dog in a three-dimensional design.

FIG. 2B illustrates a front view of one embodiment of a three-dimensional rendering for a two-piece portable mobile device protective cover depicting a dog in a three-dimensional design.

FIG. 3A illustrates a back view of one embodiment of a two-piece portable mobile device protective cover when the two-pieces are connected, which depicts a dog in a three-dimensional design.

FIG. 3B illustrates a back view of one embodiment of a two-piece portable mobile device protective cover when the two-pieces are unconnected, which depicts a dog in a three-dimensional design.

FIG. 4 illustrate a front view of one embodiment of a one-piece portable mobile device protective cover, which depicts a three-dimensional design.

FIG. 5 illustrates a back view of one embodiment of a one-piece portable mobile device protective cover, which depicts a three-dimensional design.

The accompanying drawings are intended to depict example embodiments of the present invention and should not be interpreted to limit the scope thereof. The accompanying drawings are not to be considered as drawn to scale unless explicitly noted.

### DETAILED DESCRIPTION OF THE INVENTION

While the present disclosure may be embodied in many different forms, the drawings and discussions are presented with the understanding that the present disclosure is an exemplification of the principles of one or more inventions and is not intended to limit any one of the inventions to the embodiments illustrated.

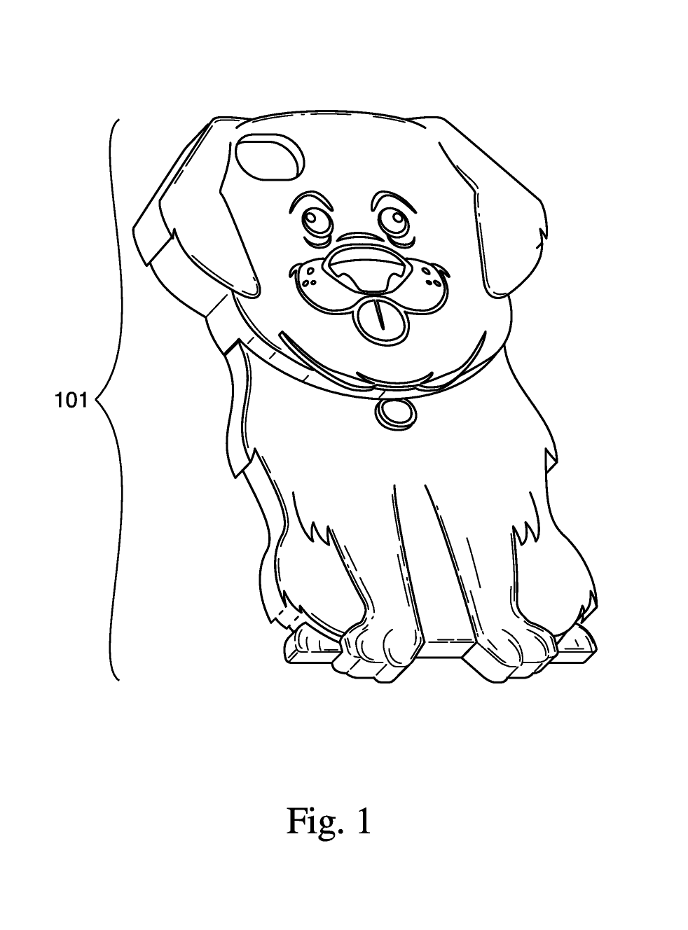

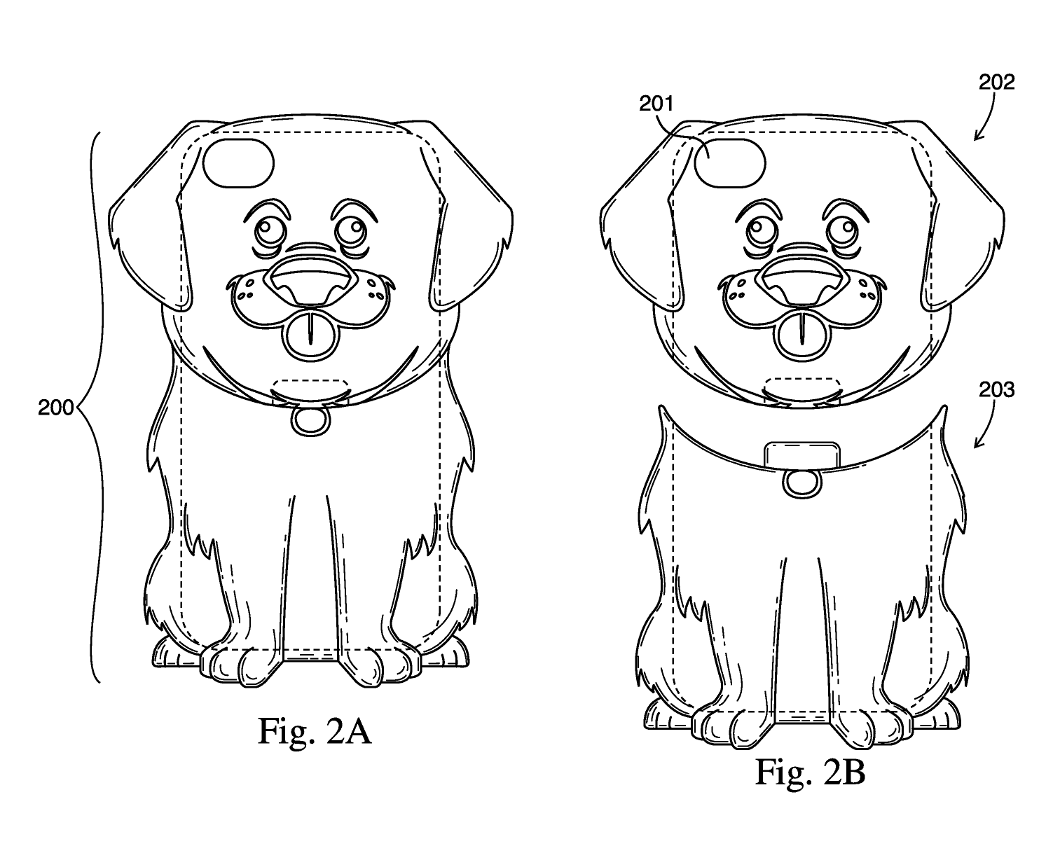

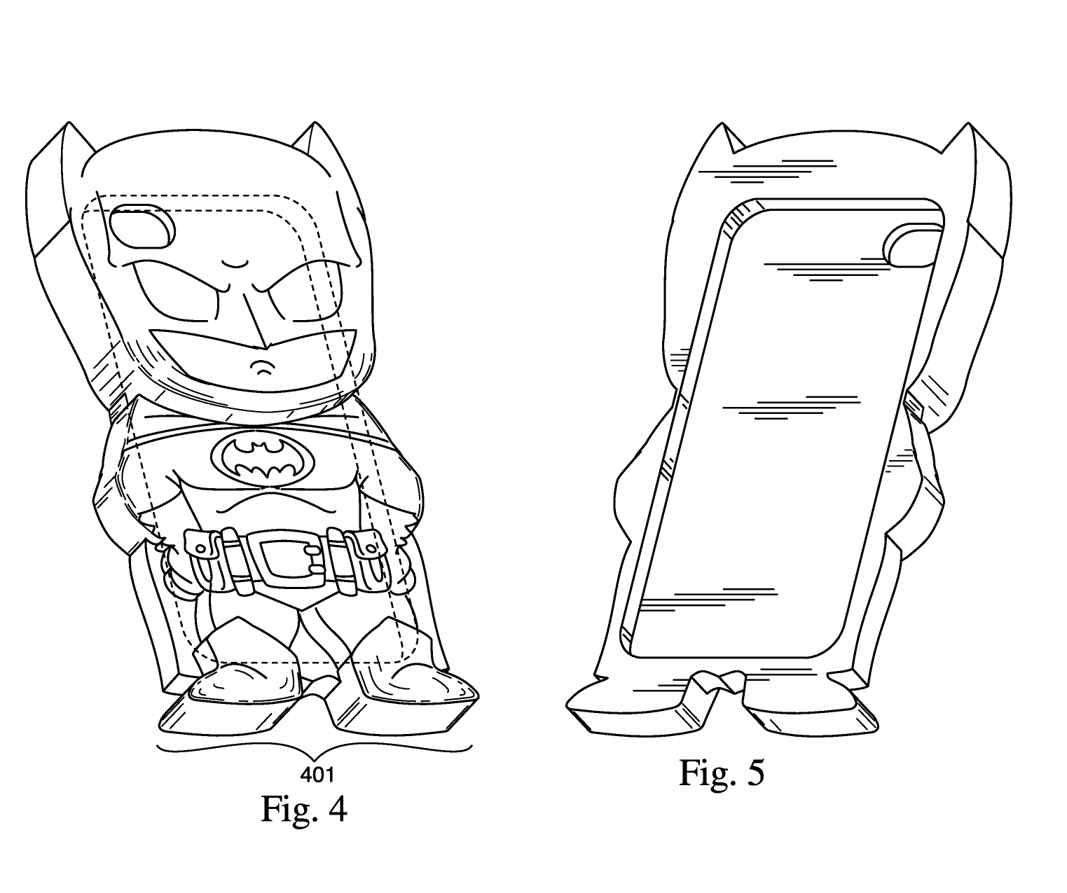

In one embodiment, as shown in FIGS. 2A-2B, the invention relates to a protective cover for a portable mobile device, comprising a top portion (202) and a bottom portion (203), wherein the top and bottom portions, each having a three-dimensional design, are operably separable from each other when not in use. As shown in FIG. 1, when the top portion (202) and a bottom portion (203) are connected they form a single unit (101). Alternatively, as show in FIGS. 4-5, the portable mobile device is a single unit. As used herein, the terms “top” and “bottom” should not be limiting and are used to assist in describing the invention. Specifically, the terms “top” and “bottom” may be used interchangeably depending on the orientation of the portable mobile device.

As shown in FIG. 2B, in one embodiment, the top portion (202) of the three-dimensional design may depict a head, while the bottom portion (203) of the three-dimensional design may depict a torso. As shown in FIG. 2A, together, the top and bottom portions depict a three-dimensional design (200), which may be a character, such as a historic figure, a cartoon character (e.g., a superhero), an animal, or a three-dimensional logo. Alternatively, the three-dimensional portable mobile device protective cover may incorporate an abstract design.

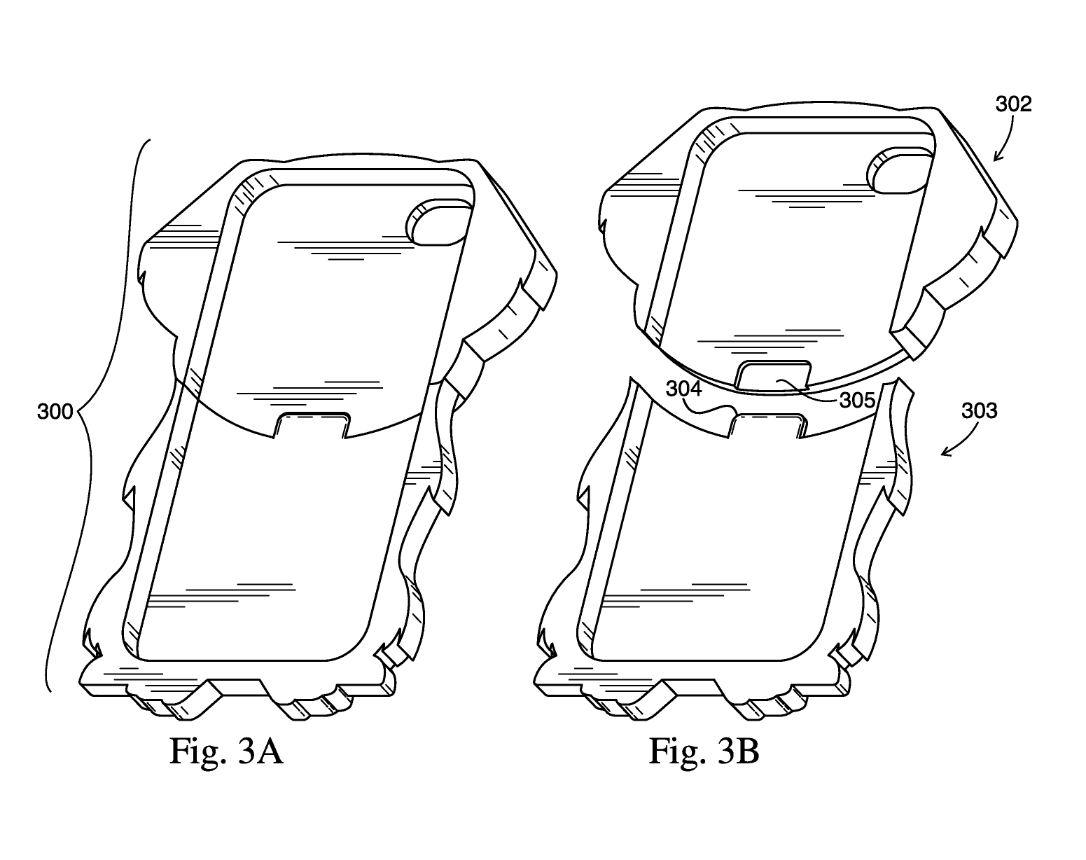

As shown in FIGS. 3A and 3B, in one embodiment, the portable mobile device is protected by the protective cover. The three-dimensional top portion (302) of the protective cover is placed over the top of the device, and the three-dimensional bottom portion (303) of the protective cover is placed under the bottom of the device. The three-dimensional top portion (302) and bottom portion (303) are moved together to be in communication with each other to form a single unit (300). As shown in FIG. 4B, the three-dimensional top and bottom portions may form a single unit by a tongue (304) and (305) groove mechanism, or any other type of mechanical fastener. It is envisioned that mechanical connectors including, but not limited to connectors that snap, slide or clasp may also be used to connect the top portion to the bottom portion. The portable mobile device is held in place within the protective cover and is protected from damage incurred by dropping or other impact.

As shown in FIG. 5, in one embodiment, the protective cover is a single piece. The portable mobile device may be mechanically connected or fastened to the three-dimensional protective cover. Examples of mechanical fasteners and connectors include, but are not limited to snaps, sliders, and clasps. Alternatively, as shown in FIG. 5, the portable mobile device may fit snuggly into the protective cover via a friction fit without a mechanical connector or fastener. As used herein, a friction fit is a fit in which the protective cover is slightly smaller than the portable mobile device and thus a certain amount of force is required to place the cover over the portable mobile device. Once the protective cover is in place on the mobile device, it may take a similar amount of force to remove the protective cover from the portable mobile device. Alternatively, the portable mobile device may be placed into the three-dimensional protective cover, which is similar to a sleeve, through a slit in top, bottom, first side or second side of the protective cover. The portable mobile device is held in place within the protective cover and is protected from damage incurred by dropping or other impact.

Portable mobile devices can be fragile and easily damaged if dropped or exposed to some other impact. It is therefore desirable to provide a protective cover for these devices. While the protective cover is exemplified in the Figures as fitted for an iPhone® mobile device or iPod® music device, one of skill in the art would understand that such three-dimensional protective covers can also be made for iPads® mobile tablet or other tablets, or other brands and styles of mobile, music or other types of communication devices. As shown at FIG. 2B at 201 the protective cover illustrated here has a hole in the top portion which is intended to enable the camera function of the portable mobile device. If the camera function is located in a different portion of the portable mobile device, the camera hole can be located in a different position on the protective cover. The protective cover can also be modified for the addition of any other portable mobile device components, such as buttons, output/input components including, but not limited to power and sound components. For example, a power component includes an adaptor, and a sound components includes external headphones.

As shown in FIG. 4, in one embodiment, the lower portion (401) of the protective cover has a thickness and weight great enough to balance the portable mobile device in an vertical upright position when the bottom side of the portable mobile device is placed in an vertical upright position on a surface. This enables a user to view the screen of the portable mobile device in a stationary hands-free vertical upright position. Alternatively, in another embodiment, a first side or second side of the protective cover is of a certain thickness and weight great enough to balance the portable mobile device in a horizontal upright position when the first side or second side is placed in a horizontal upright position on a surface. This enables a user to view a rotating screen of a portable mobile device in a stationary hands-free horizontal upright position. The thickness of the lower portion, first side, or second side may be part three-dimensional design, as shown in FIG. 4 at 401. Alternatively, it can be separate from the three-dimensional design.

The invention also relates to a method of manufacturing a protective cover for a portable mobile device. In one embodiment, the method comprises: preparing two-dimensional drawings of a desired design; loading the two-dimensional drawings into a computer; preparing a three-dimensional rendering of the design; preparing a tool of the design; injecting a material into the tool; removing and separating portions of protective cover from the tool; and forming the protective cover from the separated portions. The two-dimensional drawings can be prepared on a computer, or by any other means known in the art. Other embodiments may include alternatives to these steps.

In one embodiment, the first step of the process for manufacturing the portable mobile device protective cover is to draw the artwork for the design of the protective cover. Once the artwork is prepared, it is loaded into a computer that has the appropriate three-dimensional drawing software installed. Alternatively, the two-dimensional artwork can be prepared using a computer program. Next, a three-dimensional relief rendering is prepared from the two-dimensional drawing. Alternatively, the three dimensional rendering can be sculpted by hand or other known sculpting methods. Two graphic computer software programs available for the three-dimensional rendering are ZBrush® by Pixologic, Inc. in Los Angeles, Calif. and Maya® by Autodesk, Inc. in Mill Valley, Calif., but any three-dimensional rendering programs known to those in the art may be used.

Once the three-dimensional artwork is finished, the design is cleaned and used to prepare the injection mold tooling for the protective cover. The protective cover can be designed as two pieces that fit together to form one case by a mechanical connector or fastener, or the protective cover can be a one-piece case that attaches by a mechanical connector, fastener or some other attachment means to the portable mobile device.

Once the injection molding tool is prepared, the tool (i.e. the mold) is loaded into an injection machine. The protective cover material is injected into the tool and an injection tree of parts come out. These parts include the buttons, back plates and front plates of the case. The protective cover can be prepared from a variety of materials. These materials include, but are not limited to, polycarbonate (PC), thermoplastic polyurethane (TPU), acrylonitrile butadiene styrene (ABS) plastic, silicone, rubber, fiberglass, or metal.

Next the parts, or portions, of the protective cover are then broken off from the injection tree, cleaned, and painted. Any parts of the faceplates that need painting can be painted by using spray masks or tampo plates. Alternatively, the painting can be done by hand (e.g., for a limited version of a protective cover), or by any means known to those skilled in the art.

Once the painting is completed, the portions of the protective cover (each having three dimensional designs) are put together and sonically welded together to form the actual protective cover. The protective cover may be in one portion or two portions that fit together. In a final step, the protective covers are then sent through a spray machine to apply a rubberized coating, which can act as an additional protective layer for the portable mobile device. The rubberized coating can also provide a desirable texture and feel for the three-dimensional portable mobile device protective cover.

The foregoing description and drawings merely explain and illustrate the invention and the invention is not limited thereto. While the specification in this invention is described in relation to certain implementation or embodiments, many details are set forth for the purpose of illustration. Thus, the foregoing merely illustrates the principles of the invention. The invention may have other specific forms without departing from its spirit or essential characteristic. To those skilled in the art, the invention is susceptible to additional implementations or embodiments and certain of these details described in this application may be varied considerably without departing from the basic principles of the invention. It will thus be appreciated that those skilled in the art will be able to devise various arrangements, which, although not explicitly described or shown herein, embody the principles of the invention and, thus, are within its scope and spirit.

I claim:

1. A protective cover for a portable mobile device, comprising:
a. a top portion having a three-dimensional design; and
b. a bottom portion having a three-dimensional design,
wherein the top and bottom portions are operably separable from each other.

2. The protective cover for a portable mobile device of claim 1, wherein the top portion and the bottom portion form a single unit by a mechanical fastener.

3. The protective cover for a portable mobile device of claim 1, wherein the top portion and the bottom portion form a single unit by a mechanical connector.

4. The protective cover for a portable mobile device of claim 1, wherein the lower portion of the protective cover is configured with a thickness and weight to balance the portable mobile device in a vertical upright position on a surface.

5. A method of using the portable mobile device protective cover of claim 1 comprising:
a. separating the top portion of the protective cover from the bottom portion of the protective cover;
b. placing the portable mobile device into the bottom portion of the protective cover; and
c. placing the portable mobile device into the top portion of protective cover so that the top portion and the bottom portion hold the portable mobile device in place.

6. A method of manufacturing the three-dimensional protective cover for a portable mobile device comprising:
a. preparing a three-dimensional rendering of a two-dimensional drawing;
b. preparing a tool of the design from the three-dimensional rendering;
c. injecting a material into the tool;
d. removing and separating portions of protective cover from the tool; and
e. forming the three-dimensional protective cover from the separated portions.
